(19) United States
(12) Patent Application Publication
(10) Pub. No.: US 2026/0135352 A1
(43) Pub. Date: May 14, 2026

(54) SELF-OPTIMIZING BEAM COMBINING APPARATUS AND METHOD FOR SEMICONDUCTOR LASER BEAM QUALITY

(71) Applicant: Changchun Institute of Optics, Fine Mechanics and Physics, Chinese Academy of Sciences, Changchun (CN)

(72) Inventors: Hongbo ZHU, Changchun (CN); Chenhui ZHANG, Changchun (CN); Xingchen LIN, Changchun (CN); Yawei ZHANG, Changchun (CN); Xulan XUE, Changchun (CN); Huidan ZHANG, Changchun (CN); Yongqiang NING, Changchun (CN); Lijun WANG, Changchun (CN)

(73) Assignee: Changchun Institute of Optics, Fine Mechanics and Physics, Chinese Academy of Sciences, Changchun (CN)

(21) Appl. No.: 19/387,649

(22) Filed: Nov. 13, 2025

(30) Foreign Application Priority Data
Nov. 14, 2024 (CN) 2024116213054

(51) Int. Cl. H01S 5/40; H01S 5/00; H01S 5/14

(52) U.S. Cl. CPC H01S 5/4012; H01S 5/005; H01S 5/141; H01S 5/4025

(57) ABSTRACT

Disclosed is a self-optimizing beam combining apparatus and method for semiconductor laser beam quality in the technical field of dense spectral beam combining. The apparatus includes a semiconductor laser array, a fast axis collimator array, a slow axis collimator array, a mirror array, a volume Bragg grating array, and an external cavity mirror. A resonant external cavity is formed between a rear facet of each semiconductor laser and the external cavity mirror; after being diffracted by a volume Bragg grating, a portion of laser light transmitted to the external cavity mirror is reflected back onto the volume Bragg grating by the external cavity mirror; the volume Bragg grating utilizes its spectral selection characteristics to diffract a laser mode satisfying a Bragg diffraction condition into a chip of the semiconductor laser, and mode competition characteristics of the semiconductor laser enhance the laser mode to become a dominant lasing mode.

### CROSS-REFERENCE TO RELATED APPLICATIONS

The application claims priority to Chinese patent application No. 2024116213054, filed on Nov. 14, 2024, the entire contents of which are incorporated herein by reference.

### TECHNICAL FIELD

This disclosure relates to the technical field of dense spectral beam combining of semiconductor lasers and, in particular, to a self-optimizing beam combining apparatus and method for semiconductor laser beam quality.

### BACKGROUND

Semiconductor laser beam combining can significantly enhance laser power and beam quality. Among various semiconductor laser beam combining technologies, dense spectral beam combining based on volume Bragg gratings demonstrates significant advantages in achieving high power and high brightness. In conventional beam combining methods, it is first necessary to wavelength-lock the lasers using transmissive volume Bragg gratings, and then perform optical path combining using reflective volume Bragg gratings. This beam combining method improves the output brightness of the combined laser by increasing power, but does not improve the beam quality thereof. This results in the beam quality of the combined laser being able to approach, but not surpass, the beam quality of a single laser unit. Furthermore, each semiconductor laser participating in the beam combining must first undergo wavelength locking via the transmissive volume Bragg gratings, and then the wavelength-locked laser is diffracted at a specific angle using the reflective volume Bragg gratings. If the locked wavelength of the semiconductor laser deviates from the actual optical path angle, it will significantly impact the diffraction efficiency. Finally, conventional beam combining methods require a large number of volume Bragg gratings, which increases the cost of beam combining.

### SUMMARY

In view of the foregoing, this disclosure aims to provide a self-optimizing beam combining apparatus and method for semiconductor laser beam quality, to overcome the drawback of conventional dense spectral beam combining technology that can only increase the combined power but cannot improve the beam quality. This disclosure offers advantages such as high beam combining efficiency and low cost.

To achieve the above objective, this disclosure employs the following technical solutions:
a self-optimizing beam combining apparatus for semiconductor laser beam quality, including: a semiconductor laser array, a fast axis collimator array, a slow axis collimator array, a mirror array, a volume Bragg grating array, and an external cavity mirror, where
the semiconductor laser array emits a beam array with identical wavelengths, where the beam array sequentially passes through the fast axis collimator array, the slow axis collimator array, the mirror array, the volume Bragg grating array, and the external cavity mirror before being emitted;
the fast axis collimator array reduces a divergence angle of the beam array in a fast axis direction, the slow axis collimator array reduces a divergence angle of the beam array in a slow axis direction, the mirror array reflects the beam array emitted from the slow axis collimator array to the volume Bragg grating array, the volume Bragg grating array diffracts the beam array and causes a portion of laser light within an entire semiconductor laser spectrum that satisfies a Bragg diffraction condition to be incident on the external cavity mirror, and the external cavity mirror feeds back the laser light satisfying the Bragg diffraction condition sequentially through the volume Bragg grating array, the mirror array, the slow axis collimator array, and the fast axis collimator array along an original path back into chips of respective semiconductor lasers in the semiconductor laser array, achieving mode competition and automatic wavelength adjustment; the adjusted beam array is then combined again by sequentially passing through the fast axis collimator array, the slow axis collimator array, the mirror array, and the volume Bragg grating array; and a combined beam is output through the external cavity mirror.

Further, the semiconductor laser array includes at least two semiconductor lasers; the fast axis collimator array includes at least two fast axis collimators, with each of the fast axis collimators correspondingly arranged for each of the semiconductor lasers; the slow axis collimator array includes at least two slow axis collimators, with each of the slow axis collimators correspondingly arranged for each of the semiconductor lasers; and the mirror array includes at least two mirrors, with each of the mirrors correspondingly arranged for each of the semiconductor lasers.

Further, the semiconductor laser array is composed of single-emitter semiconductor lasers, where a front facet of each of the single-emitter semiconductor lasers is coated with an anti-reflection film, and a wavelength range emitted by the single-emitter semiconductor lasers is 800 nm to 1500 nm.

Further, the volume Bragg grating array includes at least two volume Bragg gratings, where each of the volume Bragg gratings is correspondingly arranged for each of the mirrors, and a wavelength and incident laser angle of a target beam for each of the volume Bragg gratings satisfy the following equation:

$$\vert cos {ϕ}_{0} \vert = \frac{λ}{2 Λ {n}_{av}} ;$$

where φ₀ represents the incident laser angle for the volume Bragg gratings; Λ represents a grating period; nav represents a grating refractive index; and λ represents the wavelength of the target beam.

Further, light transmitted and diffracted by each of the volume Bragg gratings is combined and then emitted through the external cavity mirror.

Further, the wavelength of the target beam satisfies the Bragg diffraction condition, and the volume Bragg gratings diffract the target beam while transmitting beams of other wavelengths.

Further, the external cavity mirror and a rear facet of each of the single-emitter semiconductor lasers included in the semiconductor laser array correspondingly form a resonant external cavity for each of the single-emitter semiconductor lasers.

Further, the external cavity mirror has a reflectivity between 5% and 20%.

Further, the volume Bragg gratings have a wavelength range of 320 nm-2,700 nm, a grating period range of 500 l/mm-3,000 l/mm, and a spectral bandwidth range of 0.2 nm-100 nm, and perform spectral selection for laser beams in a range of 700 nm-2,500 nm.

A self-optimizing beam combining method for semiconductor laser beam quality, implemented using the self-optimizing beam combining apparatus for semiconductor laser beam quality as described above, specifically including the following steps:
S1: the semiconductor laser array emits a beam array with identical wavelengths, where the beam array is incident on the volume Bragg grating array after sequentially passing through the fast axis collimator array, the slow axis collimator array, and the mirror array;
S2: the volume Bragg grating array diffracts the beam array and causes a portion of laser light within an entire semiconductor laser spectrum that satisfies a Bragg diffraction condition to be incident on the external cavity mirror, and the external cavity mirror feeds back the laser light satisfying the Bragg diffraction condition sequentially through the volume Bragg grating array, the mirror array, the slow axis collimator array, and the fast axis collimator array along an original path back into chips of respective semiconductor lasers in the semiconductor laser array, achieving mode competition and automatic wavelength adjustment; and
S3: the adjusted beam array is then combined again by sequentially passing through the fast axis collimator array, the slow axis collimator array, the mirror array, and the volume Bragg grating array, and a combined beam is output through the external cavity mirror.

Compared with the prior art, this disclosure can achieve the following beneficial effects:
(1) the self-optimizing beam combining apparatus and method for semiconductor laser beam quality described in this disclosure optimize the beam quality of the combined beam. This disclosure forms an external cavity between the rear facet of each of the semiconductor lasers and the external cavity mirror. The external cavity mirror reflects a portion of the diffracted laser beam back onto the volume Bragg gratings, which utilize their spectral selection characteristics to diffract laser modes satisfying the Bragg diffraction condition into the laser chip. Through the mode competition characteristics of the semiconductor lasers, these laser modes are enhanced and becomes the dominant lasing modes, while modes that do not satisfy the Bragg diffraction condition cannot be fed back into the chips of the respective semiconductor lasers in the semiconductor laser array. The modes that are not fed back into the chips are gradually suppressed during the mode competition process. The reduction in laser modes effectively decreases the slow axis divergence angle, thereby optimizing the beam quality of the combined beam and making it superior to that of a single device; and
(2) the self-optimizing beam combining apparatus and method for semiconductor laser beam quality described in this disclosure improve the efficiency of dense spectral beam combining. During the dense spectral beam combining process of this disclosure, the semiconductor lasers modulate the output spectrum based on the spectral selection characteristics of the volume Bragg gratings, compressing the output spectrum and automatically adjusting it to the wavelength corresponding to the highest diffraction efficiency. Therefore, even if an optical path deviation exists, the beam can be diffracted at a theoretically designed angle, thus optimizing and enhancing the efficiency of dense spectral beam combining.

### BRIEF DESCRIPTION OF THE DRAWINGS

The accompanying drawings, which constitute a part of this disclosure, are intended to provide further understanding of this disclosure. The illustrative embodiments and their descriptions in this disclosure are used to explain this disclosure and do not create an undue limitation on this disclosure. In the accompanying drawings:

FIG. 1 is a schematic structural diagram of a self-optimizing beam combining apparatus for semiconductor laser beam quality according to an embodiment of this disclosure;

FIG. 2 is a schematic diagram of a beam combining principle of a volume Bragg grating according to an embodiment of this disclosure; and

FIG. 3 is a schematic flowchart of a self-optimizing beam combining method for semiconductor laser beam quality according to an embodiment of this disclosure.

### REFERENCE SIGNS USED IN THE FIGURES

1: semiconductor laser array; 2: fast axis collimator array; 3: slow axis collimator array; 4: mirror array; 5: volume Bragg grating array; 6: external cavity mirror; 7: first laser beam; 8: second laser beam; and 9: combined beam.

### DETAILED DESCRIPTION OF THE EMBODIMENTS

To make the objectives, technical solutions, and advantages of this disclosure clearer, the following further describes this disclosure in detail with reference to the accompanying drawings and embodiments. It should be understood that the embodiments described herein are merely intended to explain this disclosure, but do not pose a limitation to this disclosure.

It should be noted that the embodiments of this disclosure and the features in the embodiments can be combined with each other in case of no conflict.

It should be understood that, in the description of this disclosure, the orientations or positional relationships indicated by the terms “central”, “longitudinal”, “transverse”, “upper”, “lower”, “front”, “rear”, “left”, “right”, “vertical”, “horizontal”, “top”, “bottom”, “inside”, “outside”, and the like are based on those shown in the accompanying drawings, intended only for the convenience of describing this disclosure and simplifying the description rather than for indicating or implying that the referred devices or elements must be provided with a particular orientation or constructed or operated in a particular orientation; therefore, these terms should not be construed as limiting this disclosure. Furthermore, the terms “first” and “second” are intended only for descriptive purposes and should not be construed as indicating or implying their relative importance or implying the quantity of technical features indicated. Therefore, features defined by “first” and “second” may explicitly or implicitly include one or more of such features. In the description of this disclosure, unless otherwise specified, “a plurality of” refers to two or more.

It should be noted that, in the description of this disclosure, unless otherwise explicitly provided and limited, the terms “mounted”, “attached”, and “connected” should be understood in a broad sense, e.g., it may be a fixed connection, a detachable connection, or an integral connection; it may be a mechanical connection or an electrical connection; it may be a direct connection or an indirect connection through an intermediate medium; or it may be a connection between two elements. For a person of ordinary skill in the art, the specific meanings of the above terms in this disclosure may be understood based on specific circumstances.

This disclosure will be described in detail below with reference to the accompanying drawings and embodiments.

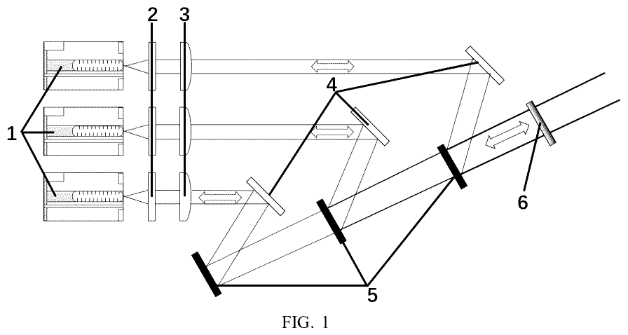

As shown in FIG. 1, a self-optimizing beam combining apparatus for semiconductor laser beam quality is provided in this disclosure, including: a semiconductor laser array 1, a fast axis collimator array 2, a slow axis collimator array 3, a mirror array 4, a volume Bragg grating array 5, and an external cavity mirror 6 (the external cavity mirror 6 has a reflectivity between 5% and 20%);

The semiconductor laser array 1 emits a beam array with identical wavelengths, where laser beams included in the beam array have a spectral width range of 5 nm to 10 nm, and the beam array sequentially passes through the fast axis collimator array 2, the slow axis collimator array 3, the mirror array 4, the volume Bragg grating array 5, and the external cavity mirror 6 before being emitted.

The beam array is sequentially collimated by the fast axis collimator array 2 and the slow axis collimator array 3; the fast axis collimator array 2 reduces a divergence angle of the beam array in a fast axis direction; the slow axis collimator array 3 reduces a divergence angle of the beam array in a slow axis direction; the mirror array 4 reflects the beam array emitted from the slow axis collimator array 3 to the volume Bragg grating array 5; the volume Bragg grating array 5 diffracts the beam array and causes a portion of laser light satisfying a Bragg diffraction condition to be incident on the external cavity mirror 6; and the external cavity mirror 6 feeds back the laser light satisfying the Bragg diffraction condition sequentially through the volume Bragg grating array 5, the mirror array 4, the slow axis collimator array 3, and the fast axis collimator array 2 along an original path back into chips of respective semiconductor lasers in the semiconductor laser array 1. Based on mode competition characteristics of the semiconductor lasers, the semiconductor laser array 1 enhances laser modes fed back along the original path to the semiconductor laser array 1 as dominant lasing modes, suppresses other stray modes, achieves mode competition and automatic wavelength adjustment, and reduces a slow axis divergence angle of the beam array emitted by the semiconductor laser array 1. The adjusted beam array is then combined again by sequentially passing through the fast axis collimator array 2, the slow axis collimator array 3, the mirror array 4, and the volume Bragg grating array 5, and a combined beam 9 is output through the external cavity mirror 6.

The semiconductor laser array 1 includes at least two semiconductor lasers; the fast axis collimator array 2 includes at least two fast axis collimators, with a focal length generally ranging from 0.1 mm to 1 mm, and each of the fast axis collimators correspondingly arranged for each of the semiconductor lasers; the slow axis collimator array 3 includes at least two slow axis collimators, with a focal length generally ranging from 5 mm to 20 mm, and each of the slow axis collimators correspondingly arranged for each of the semiconductor lasers; and the mirror array 4 includes at least two mirrors, with each of the mirrors correspondingly arranged for each of the semiconductor lasers.

The semiconductor laser array 1 is composed of single-emitter semiconductor lasers, where a front facet of each of the single-emitter semiconductor lasers is coated with an anti-reflection film (transmittance greater than 99%), and a wavelength range emitted by the single-emitter semiconductor lasers is 800 nm to 1500 nm.

The volume Bragg grating array 5 includes at least two volume Bragg gratings, where each of the volume Bragg gratings is correspondingly arranged for each of the mirrors, placement angles of the volume Bragg gratings are slightly different, and a wavelength and incident laser angle of a target beam for each of the volume Bragg gratings satisfy the following equation:

$$\vert cos {ϕ}_{0} \vert = \frac{λ}{2 Λ {n}_{av}} ;$$

where po represents the incident laser angle for the volume Bragg gratings; A represents a grating period; nav represents a grating refractive index; and λ represents the wavelength of the target beam.

Light transmitted and diffracted by each of the volume Bragg gratings is combined and then emitted through the external cavity mirror 6.

The wavelength of the target beam satisfies the Bragg diffraction condition, and the volume Bragg gratings diffract the target beam while transmitting beams of other wavelengths. That is, each of the volume Bragg gratings diffracts laser light within a laser spectrum emitted by a corresponding semiconductor laser that satisfies the diffraction equation, and transmits a laser beam diffracted by a previous volume Bragg grating (which has a certain wavelength difference from the current volume Bragg grating), thereby combining them into a single beam that is transmitted to the external cavity mirror 6, thus obtaining the final combined beam 9.

The external cavity mirror 6 and a rear facet of each of the single-emitter semiconductor lasers included in the semiconductor laser array 1 correspondingly form a resonant external cavity for each of the single-emitter semiconductor lasers. This structure allows the laser light to undergo multiple reflections between the semiconductor lasers and the external cavity mirror 6, thereby increasing the interaction between the laser light and the volume Bragg gratings.

The volume Bragg gratings exhibit good spectral selectivity. In conventional dense spectral beam combining, the spectral selectivity of the volume Bragg gratings manifests as changes in diffraction angle for different laser modes. Laser modes within their spectral selection bandwidth are diffracted with high efficiency, while laser modes outside their spectral selection bandwidth are emitted with a certain directional deviation, thereby degrading beam quality.

This disclosure arranges the external cavity mirror 6 in the laser emission direction of dense spectral beam combining and forms an external cavity feedback mechanism with the semiconductor lasers. By combining the spectral selectivity of the volume Bragg gratings with the mode competition effect of the semiconductor lasers, it effectively reduces the number of transverse modes in the semiconductor lasers, thereby decreasing the divergence angle and fundamentally improving the beam quality of the combined beam source. This breaks through the current bottleneck where the beam quality of dense spectral beam combining sources is limited by the individual devices. Specifically, in this disclosure, the volume Bragg gratings only allow laser light of specific wavelengths that satisfy the Bragg diffraction condition to pass through. Only the laser light of specific wavelengths can be reflected back into the semiconductor lasers, while laser light of other wavelengths is filtered out. The semiconductor lasers, with their mode competition characteristics, enhance the laser modes satisfying the Bragg diffraction condition to become the dominant lasing modes. These laser modes receive feedback from the external cavity mirror 6, thereby being enhanced within the lasers. Laser modes that do not satisfy the Bragg diffraction condition cannot be fed back into the chips of the respective semiconductor lasers and are thus suppressed and reduced during the mode competition process. This results in a reduction of laser modes output by the semiconductor lasers. The reduction in laser modes lowers the slow axis divergence angle of the semiconductor lasers and improves the beam quality.

Through the self-optimization process, the laser modes of the semiconductor lasers are reduced, leading to a decrease in the slow axis divergence angle. The output spectrum of each of the semiconductor lasers narrows and automatically adjusts to the wavelength with the highest diffraction efficiency of the volume Bragg gratings.

Due to the spectral selectivity of the volume Bragg gratings, a self-adjusting effect can be achieved, reducing the necessity for external interference and improving the efficiency of dense spectral beam combining. Compared with conventional dense spectral beam combining technologies, this disclosure reduces the number of volume Bragg grating devices used, thereby saving costs. Furthermore, the reduced usage of volume Bragg gratings also decreases the possibility of diffraction efficiency being affected by positional deviations of the volume Bragg gratings.

In this disclosure, the volume Bragg gratings have a wavelength range of 320 nm-2,700 nm, a grating period range of 500 l/mm-3,000 l/mm, and a spectral bandwidth range of 0.2 nm-100 nm, and perform spectral selection for laser beams in a range of 700 nm-2,500 nm.

### Example 1

Three semiconductor lasers with an emission wavelength of 940 nm and an emission width of 95 μm were selected to form a laser array, and three volume Bragg gratings with a diffraction center wavelength of 976 nm were selected to form a volume Bragg grating array 5. The center wavelengths of three target beams ultimately desired by the user were 974.5 nm, 976 nm, and 977.5 nm, respectively. Other parameters of the gratings were as follows: grating period Λ: 3,000 l/mm; grating refractive index nav: 1.485. Using the above parameters, the incident angles for the three volume Bragg gratings were calculated as follows: 15.743°, 15°, and 14.221°, respectively. Mirrors corresponding to the three volume Bragg gratings were placed such that the laser incident angles to the three volume Bragg gratings were 15.743°, 15°, and 14.221°, respectively.

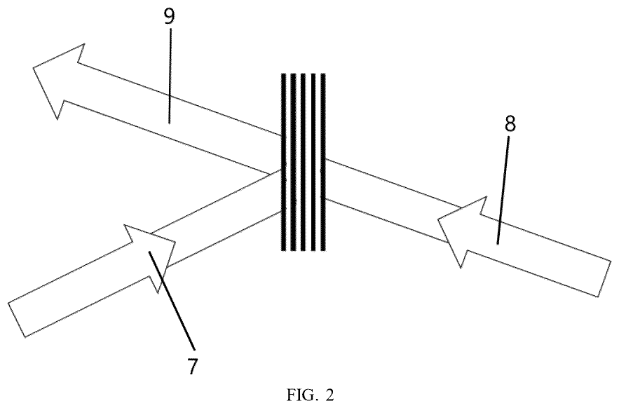

The volume Bragg gratings were able to achieve beam combining of two laser beams with a wavelength interval of 1.5 nm. As shown in FIG. 2, the combining principle was as follows: a first laser beam 7 should be incident on the volume Bragg gratings at an angle satisfying a Bragg condition, and was output with an efficiency of 99% after diffraction by the volume Bragg gratings; a second laser beam 8 had a wavelength difference of 1.5 nm from the diffracted first laser beam 7, and after being transmitted through the volume Bragg gratings, the second laser beam 8 spatially overlapped with the diffracted first laser beam 7 to achieve beam combining.

Finally, a portion of laser light transmitted to the external cavity mirror 6 after diffraction by the volume Bragg gratings was reflected back onto the volume Bragg gratings by the external cavity mirror 6. The volume Bragg gratings utilized their spectral selection characteristics to diffract laser modes satisfying the Bragg diffraction condition into the chips of the lasers, while laser modes that did not satisfy the Bragg diffraction condition could not be fed back into the chips of the lasers and were thus suppressed and reduced. This ultimately modulated the wavelengths of the semiconductor lasers to 974.5 nm, 976 nm, and 977.5 nm.

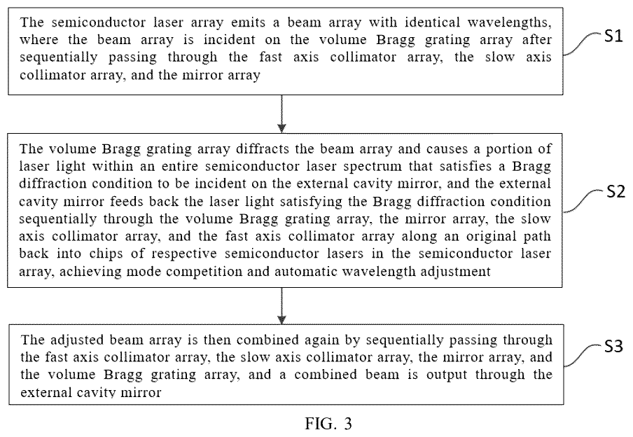

As shown in FIG. 3, a self-optimizing beam combining method for semiconductor laser beam quality is provided in this disclosure, implemented using the self-optimizing beam combining apparatus for semiconductor laser beam quality as described above, specifically including the following steps:
S1: the semiconductor laser array 1 emits a beam array with identical wavelengths, where the beam array is incident on the volume Bragg grating array 5 after sequentially passing through the fast axis collimator array 2, the slow axis collimator array 3, and the mirror array 4;
S2: the volume Bragg grating array 5 diffracts the beam array and causes a portion of laser light within an entire semiconductor laser spectrum that satisfies a Bragg diffraction condition to be incident on the external cavity mirror 6, and the external cavity mirror 6 feeds back the laser light satisfying the Bragg diffraction condition sequentially through the volume Bragg grating array 5, the mirror array 4, the slow axis collimator array 3, and the fast axis collimator array 2 along an original path back into chips of respective semiconductor lasers in the semiconductor laser array 1, achieving mode competition and automatic wavelength adjustment; and
S3: the adjusted beam array is then combined again by sequentially passing through the fast axis collimator array 2, the slow axis collimator array 3, the mirror array 4, and the volume Bragg grating array 5, and a combined beam 9 is output through the external cavity mirror 6.

It should be understood that various forms of processes shown above may be used, with steps reordered, added, or deleted. For example, the steps described in this disclosure may be executed in parallel, sequentially, or in different orders, which are not limited herein, as long as the desired results of the technical solutions disclosed herein can be achieved.

The above embodiments do not constitute a limitation on the scope of protection of this disclosure. Those skilled in the art should understand that various modifications, combinations, sub-combinations, and substitutions may be made according to design requirements and other factors. Any modifications, equivalent replacements, and improvements made within the spirit and principle of this disclosure shall fall within the scope of protection of this disclosure.

What is claimed is:

1. A self-optimizing beam combining apparatus for semiconductor laser beam quality, comprising: a semiconductor laser array, a fast axis collimator array, a slow axis collimator array, a mirror array, a volume Bragg grating array, and an external cavity mirror, wherein
the semiconductor laser array emits a beam array with identical wavelengths, wherein the beam array sequentially passes through the fast axis collimator array, the slow axis collimator array, the mirror array, the volume Bragg grating array, and the external cavity mirror before being emitted;
the fast axis collimator array reduces a divergence angle of the beam array in a fast axis direction, the slow axis collimator array reduces a divergence angle of the beam array in a slow axis direction, the mirror array reflects the beam array emitted from the slow axis collimator array to the volume Bragg grating array, the volume Bragg grating array diffracts the beam array and causes a portion of laser light within an entire semiconductor laser spectrum that satisfies a Bragg diffraction condition to be incident on the external cavity mirror, and the external cavity mirror feeds back the laser light satisfying the Bragg diffraction condition sequentially through the volume Bragg grating array, the mirror array, the slow axis collimator array, and the fast axis collimator array along an original path back into chips of respective semiconductor lasers in the semiconductor laser array, achieving mode competition and automatic wavelength adjustment; the adjusted beam array is then combined again by sequentially passing through the fast axis collimator array, the slow axis collimator array, the mirror array, and the volume Bragg grating array; and a combined beam is output through the external cavity mirror;
the semiconductor laser array comprises at least two semiconductor lasers; the fast axis collimator array comprises at least two fast axis collimators, with each of the fast axis collimators correspondingly arranged for each of the semiconductor lasers; the slow axis collimator array comprises at least two slow axis collimators, with each of the slow axis collimators correspondingly arranged for each of the semiconductor lasers; the mirror array comprises at least two mirrors, with each of the mirrors correspondingly arranged for each of the semiconductor lasers; and
the volume Bragg grating array comprises at least two volume Bragg gratings, wherein each of the volume Bragg gratings is correspondingly arranged for each of the mirrors, and a wavelength and incident laser angle of a target beam for each of the volume Bragg gratings satisfy the following equation:
$$\vert cos {ϕ}_{0} \vert = \frac{λ}{2 Λ {n}_{av}} ;$$
wherein do represents the incident laser angle for the volume Bragg gratings; Λ represents a grating period; nav represents a grating refractive index; and λ represents the wavelength of the target beam.

2. The self-optimizing beam combining apparatus for semiconductor laser beam quality of claim 1, wherein the semiconductor laser array is composed of single-emitter semiconductor lasers, wherein a front facet of each of the single-emitter semiconductor lasers is coated with an anti-reflection film, and a wavelength range emitted by the single-emitter semiconductor lasers is 800 nm to 1500 nm.

3. The self-optimizing beam combining apparatus for semiconductor laser beam quality of claim 1, wherein light transmitted and diffracted by each of the volume Bragg gratings is combined and then emitted through the external cavity mirror.

4. The self-optimizing beam combining apparatus for semiconductor laser beam quality of claim 1, wherein the wavelength of the target beam satisfies the Bragg diffraction condition, and the volume Bragg gratings diffract the target beam while transmitting beams of other wavelengths.

5. The self-optimizing beam combining apparatus for semiconductor laser beam quality of claim 2, wherein the external cavity mirror and a rear facet of each of the single-emitter semiconductor lasers comprised in the semiconductor laser array correspondingly form a resonant external cavity for each of the single-emitter semiconductor lasers.

6. The self-optimizing beam combining apparatus for semiconductor laser beam quality of claim 1, wherein the external cavity mirror has a reflectivity between 5% and 20%.

7. The self-optimizing beam combining apparatus for semiconductor laser beam quality of claim 1, wherein the volume Bragg gratings have a wavelength range of 320 nm-2,700 nm, a grating period range of 500 l/mm-3,000 l/mm, and a spectral bandwidth range of 0.2 nm-100 nm, and perform spectral selection for laser beams in a range of 700 nm-2,500 nm.

8. A self-optimizing beam combining method for semiconductor laser beam quality, implemented using the self-optimizing beam combining apparatus for semiconductor laser beam quality of claim 1, specifically comprising the following steps:
S1: the semiconductor laser array emits a beam array with identical wavelengths, wherein the beam array is incident on the volume Bragg grating array after sequentially passing through the fast axis collimator array, the slow axis collimator array, and the mirror array;
S2: the volume Bragg grating array diffracts the beam array and causes a portion of laser light within an entire semiconductor laser spectrum that satisfies a Bragg diffraction condition to be incident on the external cavity mirror, and the external cavity mirror feeds back the laser light satisfying the Bragg diffraction condition sequentially through the volume Bragg grating array, the mirror array, the slow axis collimator array, and the fast axis collimator array along an original path back into chips of respective semiconductor lasers in the semiconductor laser array, achieving mode competition and automatic wavelength adjustment; and
S3: the adjusted beam array is then combined again by sequentially passing through the fast axis collimator array, the slow axis collimator array, the mirror array, and the volume Bragg grating array, and a combined beam is output through the external cavity mirror.
